(19) United States
(12) Patent Application Publication
(10) Pub. No.: US 2026/0211376 A1
(43) Pub. Date: Jul. 23, 2026

(54) TIME-TO-DIGITAL CONVERTER AND CALIBRATION METHOD FOR PERFORMING TIME-TO-DIGITAL CONVERSION ON INPUT SIGNAL

(71) Applicant: Realtek Semiconductor Corp., HsinChu (TW)

(72) Inventors: Yu-Te Kao, HsinChu (TW); Jiunn-Way Miaw, HsinChu (TW); Chih-Chiang Chang, HsinChu (TW)

(73) Assignee: Realtek Semiconductor Corp., HsinChu (TW)

(21) Appl. No.: 19/445,676

(22) Filed: Jan. 12, 2026

(30) Foreign Application Priority Data
Jan. 17, 2025 (TW) 114101940

(51) Int. Cl. G04F 10/00; H03K 19/21

(52) U.S. Cl. CPC G04F 10/005; H03K 19/21

(57) ABSTRACT

A time-to-digital converter and a calibration method for performing time-to-digital conversion on an input signal are provided. The time-to-digital converter includes a time counter, a calibration circuit and an adder. The time counter starts counting in response to a first edge of the input signal and stops counting in response to a second edge of the input signal, to generate a preliminary counting value. The calibration generates a first determination bit according to the first edge of the input signal and a first edge of a clock signal, generates a second determination bit according to the second edge of the input signal and a second edge of the clock signal, and generates a calibration value according to the first determination bit and the second determination bit. In addition, the adder adds the calibration value to the preliminary counting value to generate a final counting value.

### BACKGROUND OF THE INVENTION

### 1. Field of the Invention

The present invention is related to circuits for time measurements, and more particularly, to a time-to-digital converter (TDC) and a calibration method for performing time-to-digital conversion on an input signal.

### 2. Description of the Prior Art

Time-to-digital converters typically perform counting based on a high-speed clock signal within a time interval, such that a length of the time interval can be represented by the number of cycles of the clock signal. When a starting time point and/or an ending time point of the time interval are not synchronized with the clock signal, an error between a time length represented by a digital signal generated by the aforementioned time-to-digital conversion mechanism and a time length to be measured can reach up to T_{CLK} (where T_{CLK} is the cycle period of the clock signal).

Some related arts improve the precision of time-to-digital conversion by increasing the number of stages of unit circuits. This, however, results in a significant increase in circuit area, susceptibility to process variations, and a significant increase in power consumption. Architectures proposed by other related arts may significantly increase overall circuit complexity, thereby increasing difficulty and risk of implementation.

Thus, there is a need for a novel architecture of a time-to-digital converter and an associated method which can improve the precision of time-to-digital conversion without introducing any side effect or in a way that is less likely to introduce side effects.

### SUMMARY OF THE INVENTION

An objective of the present invention is to provide a time-to-digital converter (TDC) and a calibration method for performing time-to-digital conversion on an input signal, which can improve an overall performance of the TDC without introducing any side effect or in a way that is less likely to introduce side effects.

At least one embodiment of the present invention provides a TDC. The TDC comprises a time counter, a calibration circuit and an adder, where the adder is coupled to the time counter and the calibration circuit. The time counter is configured to start counting at a first time point of a first edge of an input signal and stop counting at a second time point of a second edge of the input signal, to generate a preliminary counting value. The calibration circuit is configured to generate a first determination bit according to the first edge of the input signal and a first edge of a clock signal, generate a second determination bit according to the second edge of the input signal and a second edge of the clock signal, and generate a calibration value according to the first determination bit and the second determination bit. In addition, the adder is configured to add the calibration value to the preliminary counting value to generate a final counting value.

At least one embodiment of the present invention provides a calibration method for performing time-to-digital conversion on an input signal. The calibration method comprises: starting counting at a first time point of a first edge of an input signal and stopping counting at a second time point of a second edge of the input signal, to generate a preliminary counting value; generating a first determination bit according to the first edge of the input signal and a first edge of a clock signal; generating a second determination bit according to the second edge of the input signal and a second edge of the clock signal; generating a calibration value according to the first determination bit and the second determination bit; and adding the calibration value to the preliminary counting value to generate a final counting value.

The TDC and the calibration method provided by the embodiments of the present invention can determine whether the output of the TDC needs to be calibrated (e.g. incremented by one) according to a relationship of the input signal and the clock signal at a starting time point and a relationship of the input signal and the clock signal at an ending point, to thereby reduce an error between a time-to-digital conversion result and a time length to be measured within ±0.5×T_{CLK} (where T_{CLK} is a cycle period of the clock signal). In addition, the embodiments of the present invention will not significantly increase the circuit area and power consumption. Thus, the present invention can improve the precision of the TDC without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an electronic device comprising a time-to-digital converter according to an embodiment of the present invention.

FIG. 2 is a diagram illustrating a concept of time-to-digital conversion according to an embodiment of the present invention.

FIG. 3 is a diagram illustrating a calibration circuit according to an embodiment of the present invention.

FIG. 4 is a diagram illustrating associated signals of the calibration circuit under a first condition according to an embodiment of the present invention.

FIG. 5 is a diagram illustrating associated signals of the calibration circuit under a second condition according to an embodiment of the present invention.

FIG. 6 is a diagram illustrating associated signals of the calibration circuit under a third condition according to an embodiment of the present invention.

FIG. 7 is a diagram illustrating associated signals of the calibration circuit under a fourth condition according to an embodiment of the present invention.

FIG. 8 is a diagram illustrating a working flow of a calibration method for performing time-to-digital conversion on an input signal according to an embodiment of the present invention.

### DETAILED DESCRIPTION

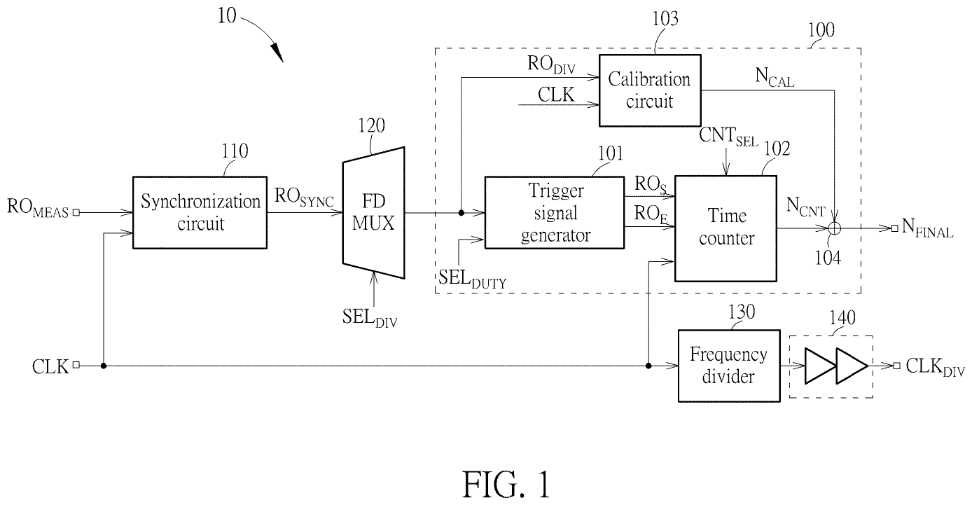

FIG. 1 is a diagram illustrating an electronic device 10 comprising a time-to-digital converter (TDC) 100 according to an embodiment of the present invention. In this embodiment, the electronic device 10 may be a process monitoring chip for measuring a cycle period of a ring oscillator, to thereby determine a process variation condition of a wafer to which the process monitoring chip belongs, but the present invention is not limited thereto. As shown in FIG. 1, the electronic device 10 may comprise the TDC 100, a synchronization circuit 110, a frequency division multiplexer 120, a frequency divider 130 and an output buffer 140, where an input of the frequency division multiplexer 120 is coupled to an output of the synchronization circuit 110, and an input of the TDC 100 is coupled to an output of the frequency division multiplexer 120. In addition, an input of the output buffer 140 is coupled to an output of the frequency divider 130. In this embodiment, the synchronization circuit 110 is configured to receive an oscillation signal RO_{MEAS} from the ring oscillator (not shown) and sample the oscillation signal RO_{MEAS} according to a clock signal CLK to generate a synchronized oscillation signal RO_{SYNC}. The frequency division multiplexer 120 is configured to perform frequency division on the synchronized oscillation signal RO_{SYNC} to generate a plurality of frequency division results (e.g. frequency division results of dividing by 1, dividing by 16, dividing by 32, and dividing by 64), and select one of these frequency division results according to a selection signal SEL_{DIV} to be outputted as an input signal RO_{DIV} of the TDC 100. The TDC 100 is configured to perform time-to-digital conversion on a time length of a high logic level duty cycle (e.g. a period having a logic value “1”) or a low logic level duty cycle (e.g. a period having a logic value “0”) of the input signal RO_{DIV}, to generate a final counting value N_{FINAL}, where the final counting value N_{FINAL} may be used to represent a ratio between the time length to be measured of the input signal RO_{DIV} (e.g. the time length of the high logic level duty cycle or the low logic level duty cycle mentioned above) and a cycle period T_{CLK} of the clock signal CLK. The frequency divider 130 is configured to perform frequency division on the clock signal CLK, and the output buffer 140 is configured to output a frequency-divided clock signal CLK_{DIV}. As a divisor of the frequency division multiplexer 120 and a divisor of the frequency divider 130 are both controllable and known information, a test engineer may detect the final counting value N_{FINAL} and the frequency-divided clock signal CLK_{DIV} and accordingly calculate a frequency of the oscillation signal RO_{MEAS}, to thereby determine the process variation condition of the wafer to which the electronic device 10 belongs, but the present invention is not limited thereto.

In this embodiment, the TDC 100 may comprise a trigger signal generator 101, a time counter 102, a calibration circuit 103 and an adder 104, where the time counter 102 is coupled to the trigger signal generator 101, and the adder 104 is coupled to the time counter 102 and the calibration circuit 103. In this embodiment, the trigger signal generator 101 is configured to generate trigger signals RO_{S} and RO_{E} corresponding to the input signal RO_{DIV} according to a selection signal SEL_{DUTY}. For example, when the selection signal SEL_{DUTY} has a first logic value (e.g. the logic value “1”), the trigger signal generator 101 may generate the trigger signal RO_{S} (more particularly, a rising edge of the trigger signal RO_{S}) corresponding to a rising edge of the input signal RO_{DIV} and the trigger signal RO_{E} (more particularly, a rising edge of the trigger signal RO_{E}) corresponding to a falling edge of the input signal RO_{DIV}, where this falling edge of the input signal RO_{DIV} is a first falling edge after this rising edge of the input signal RO_{DIV}. In another example, when the selection signal SEL_{DUTY} has a second logic value (e.g. the logic value “0”), the trigger signal generator 101 may generate the trigger signal RO_{S} (more particularly, a rising edge of the trigger signal RO_{S}) corresponding to a falling edge of the input signal RO_{DIV} and the trigger signal RO_{E} (more particularly, a rising edge of the trigger signal RO_{E}) corresponding to a rising edge of the input signal RO_{DIV}, where this rising edge of the input signal RO_{DIV} is a first rising edge after this falling edge of the input signal RO_{DIV}. In addition, the time counter 102 is configured to start counting at a first time point of a first edge of the input signal RO_{DIV} (e.g. starting counting in response to the rising edge of the trigger signal RO_{S}) and stop counting at a second time point of a second edge of the input signal RO_{DIV} (e.g. stopping counting in response to the rising edge of the trigger signal RO_{E}), to generate a preliminary counting value N_{CNT}. Thus, when the selection signal SEL_{DUTY} has the first logic value (e.g. the logic value “1”), the time counter 102 may generate the preliminary counting value N_{CNT} according to the time length of the high logic level duty cycle of the input signal RO_{DIV}; and when the selection signal SEL_{DUTY} has the second logic value (e.g. the logic value “0”), the time counter 102 may generate the preliminary counting value N_{CNT} according to the time length of the low logic level duty cycle of the input signal RO_{DIV}. In addition, the calibration circuit 103 is configured to generate a first determination bit according to the first edge of the input signal RO_{DIV} and a first edge of the clock signal CLK, and generate a second determination bit according to the second edge of the input signal RO_{DIV} and a second edge of the clock signal CLK, where the calibration circuit 103 may further generate a calibration value N_{CAL} according to the first determination bit and the second determination bit. Furthermore, the adder 104 is configured to add the calibration value N_{CAL} to the preliminary counting value N_{CNT} to generate the final counting value N_{FINAL}.

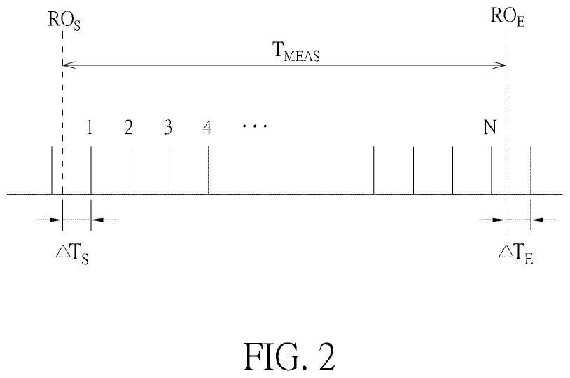

FIG. 2 is a diagram illustrating a concept of time-to-digital conversion according to an embodiment of the present invention, where a dashed line on the left side of FIG. 2 may represent the first edge of the input signal RO_{DIV} (e.g. the rising edge of the trigger signal RO_{S}), and a dashed line on the right side of FIG. 2 may represent the second edge of the input signal RO_{DIV} (e.g. the rising edge of the trigger signal RO_{E}). In one embodiment, the preliminary counting value N_{CNT} generated by the time counter 102 when a selection signal CNT_{SEL} is set to the logic value “1” may represent a number of rising edges of the clock signal CLK during a counting period T_{MEAS} between the first time point (e.g. the time point of the rising edge of the trigger signal RO_{S}) and the second time point (e.g. the time point of the rising edge of the trigger signal RO_{E}), where the first edge of the clock signal CLK may represent a first rising edge of the clock signal CLK after the first edge of the input signal RO_{DIV} (e.g. a first solid line to the right of the dashed line labeled RO_{S}), and the second edge of the clock signal CLK may represent a first rising edge of the clock signal CLK after the second edge of the input signal RO_{DIV} (e.g. a first solid line to the right of the dashed line labeled RO_{E}). In another embodiment, the preliminary counting value N_{CNT} generated by the time counter 102 when the selection signal CNT_{SEL} is set to the logic value “0” may represent a number of falling edges of the clock signal CLK during the counting period T_{MEAS} between the first time point (e.g. the time point of the rising edge of the trigger signal RO_{S}) and the second time point (e.g. the time point of the rising edge of the trigger signal RO_{E}), where the first edge of the clock signal CLK may represent a first falling edge of the clock signal CLK after the first edge of the input signal RO_{DIV} (e.g. the first solid line to the right of the dashed line labeled RO_{S}), and the second edge of the clock signal CLK may represent a first falling edge of the clock signal CLK after the second edge of the input signal RO_{DIV} (e.g. the first solid line to the right of the dashed line labeled RO_{E}).

It should be noted that, as the first edge and the second edge of the input signal RO_{DIV} may be asynchronous with the clock signal CLK, a time difference ΔT_{S} between the first edge of the input signal RO_{DIV} and the first edge of the clock signal CLK and/or a time difference ΔT_{E} between the second edge of the input signal RO_{DIV} and the second edge of the clock signal CLK may affect the precision of the preliminary counting value N_{CNT}. For example, although the time counter 102 counts N cycle periods T_{CLK} of the clock signal CLK during the counting period T_{MEAS} (N is a positive integer), an error between the time length of the counting period T_{MEAS} (i.e. the time length to be measured of the input signal RO_{DIV}) and N×T_{CLK} may reach T_{CLK}. Thus, the calibration circuit 103 may determine whether the time difference ΔT_{S} between the first edge of the input signal RO_{DIV} and the first edge of the clock signal CLK is greater than a half cycle of the clock signal CLK (i.e. 0.5×T_{CLK}) to generate the first determination bit, and determine whether the time difference ΔT_{E} between the second edge of the input signal RO_{DIV} and the second edge of the clock signal CLK is greater than the half cycle of the clock signal CLK (i.e. 0.5×T_{CLK}) to generate the second determination bit. Thus, the first determination bit may indicate whether the time difference ΔT_{S} between the first edge of the input signal RO_{DIV} and the first edge of the clock signal CLK is greater than the half cycle of the clock signal CLK, and the second determination bit may indicate whether the time difference ΔT_{E} between the second edge of the input signal RO_{DIV} and the second edge of the clock signal CLK is greater than the half cycle of the clock signal CLK. When the first determination bit indicates that the time difference ΔT_{S} is greater than the half cycle of the clock signal CLK (i.e. ΔT_{S}>0.5×T_{CLK}) and the second determination bit indicates that the time difference ΔT_{E} is less than the half cycle of the clock signal CLK (i.e. ΔT_{E}<0.5×T_{CLK}), the calibration value N_{CAL} generated by the calibration circuit 103 is one, and the final counting value N_{FINAL} is equal to the preliminary counting value N_{CNT} plus one. When the first determination bit indicates that the time difference ΔT_{S} is less than the half cycle of the clock signal CLK (i.e. ΔT_{S}<0.5×T_{CLK}) or the second determination bit indicates that the time difference ΔT_{E} is greater than the half cycle of the clock signal CLK (i.e. ΔT_{E}>0.5×T_{CLK}), the calibration value N_{CAL} generated by the calibration circuit 103 is zero, and the final counting value N_{FINAL} is equal to the preliminary counting value N_{CNT}.

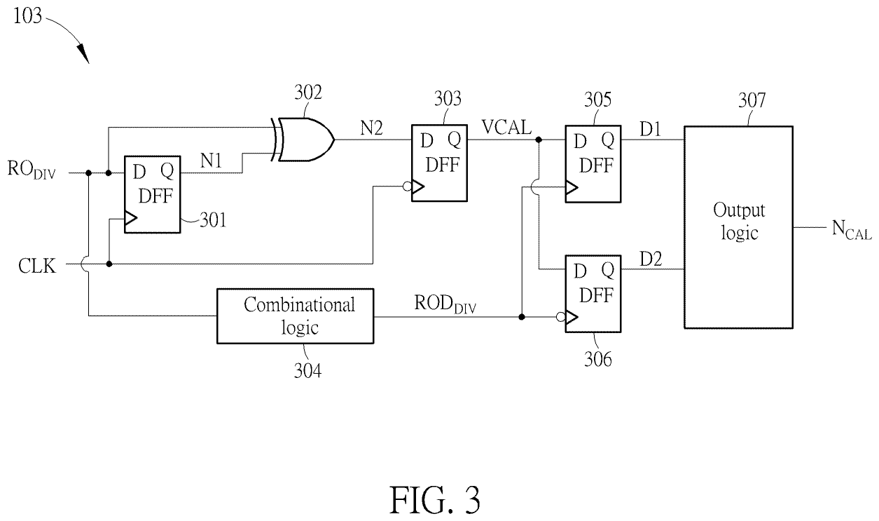

FIG. 3 is a diagram illustrating the calibration circuit 103 according to an embodiment of the present invention. As shown in FIG. 3, the calibration circuit 103 may comprise a first flip-flop such as a flip-flop 301, an exclusive-OR (XOR) gate 302, and a second flip-flop such as a flip-flop 303, where the XOR gate 302 is coupled to the flip-flop 301, and the flip-flop 303 is coupled to the XOR gate 302. In this embodiment, the flip-flop 301 is configured to sample the input signal RO_{DIV} according to rising edges of the clock signal CLK to generate a first node signal such as a node signal N1, the XOR gate 302 is configured to perform an exclusive-OR operation on the input signal RO_{DIV} and the node signal N1 to generate a second node signal such as a node signal N2, and the flip-flop 303 is configured to sample the node signal N2 according to falling edges of the clock signal CLK to generate a calibration signal VCAL, where a value of the calibration signal VCAL at a first delayed time point corresponding to the first time point may represent the first determination bit such as a determination bit D1, and a value of the calibration signal VCAL at a second delayed time point corresponding to the second time point may represent the second determination bit such as a determination bit D2. The calibration circuit 103 may further comprise a delay circuit such as a combinational logic 304, a third flip-flop such as a flip-flop 305, a fourth flip-flop such as a flip-flop 306, and an output logic 307, where the flip-flops 305 and 306 are both coupled to the flip-flop 303 and the combinational logic 304, and the output logic 307 is coupled to the flip-flops 305 and 306. In particular, the combinational logic 304 is configured to delay the input signal RO_{DIV} to generate a delayed input signal ROD_{DIV}, where the combinational logic 304 delays the first edge of the input signal RO_{DIV} at the first time point and the second edge of the input signal RO_{DIV} at the second time point to generate a first delayed edge of the delayed input signal ROD_{DIV} at the first delayed time point and a second delayed edge of the delayed input signal ROD_{DIV} at the second delayed time point, respectively. In addition, the flip-flop 305 is configured to sample the calibration signal VCAL at the first delayed time point according to the first delayed edge of the delayed input signal ROD_{DIV} to generate the determination bit D1, and the flip-flop 306 is configured to sample the calibration signal VCAL at the second delayed time point according to the second delayed edge of the delayed input signal ROD_{DIV} to generate the determination bit D2, where the output logic 307 may generate the calibration value N_{CAL} according to the determination bits D1 and D2.

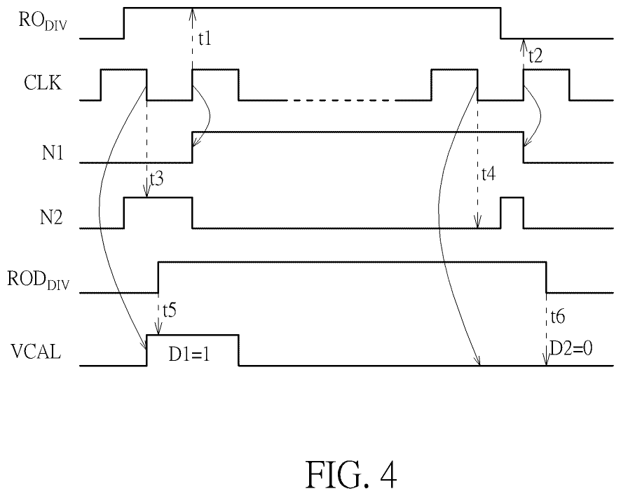

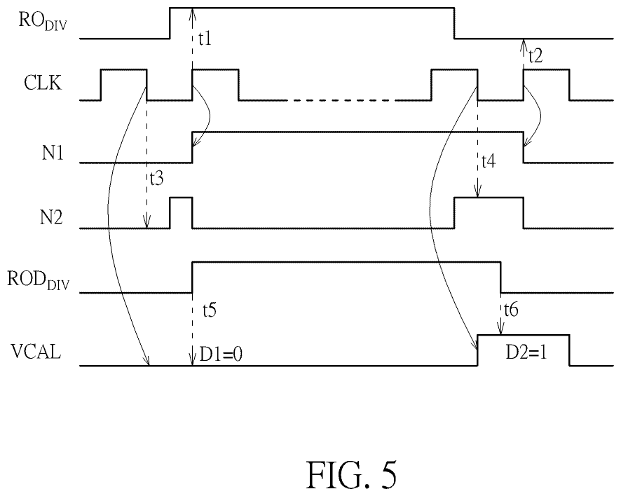

FIG. 4 is a diagram illustrating associated signals (e.g. the input signal RO_{DIV}, the clock signal CLK, the node signals N1 and N2, the delayed input signal ROD_{DIV} and the calibration signal VCAL) of the calibration circuit 103 under a first condition (e.g. ΔT_{S}>0.5×T_{CLK} and ΔT_{E}<0.5×T_{CLK}) according to an embodiment of the present invention. In this embodiment, the flip-flop 301 may pull the node signal N1 to the logic value “1” in response to a rising edge of the clock signal CLK at a time point t1, and pull the node signal N1 to the logic value “0” in response to a rising edge of the clock signal CLK at a time point t2. As the time difference ΔT_{S} is greater than the half cycle of the clock signal CLK, the node signal N2 has the logic value “1” at a time point t3, such that the flip-flop 303 may pull the calibration signal VCAL to the logic value “1” in response to a falling edge of the clock signal CLK at the time point t3. In addition, as the time difference ΔT_{E} is less than the half cycle of the clock signal CLK, the node signal N2 has the logic value “0” at a time point t4, such that the flip-flop 303 may maintain the calibration signal VCAL at the logic value “0” at the time point t4 instead of pulling the calibration signal VCAL to the logic value “1” in response to a falling edge of the clock signal CLK at the time point t4. Thus, the flip-flop 305 may output the determination bit D1 having the logic value “1” in response to a rising edge of the delayed input signal ROD_{DIV} at a time point t5, and the flip-flop 306 may output the determination bit D2 having the logic value “0” in response to a falling edge of the delayed input signal ROD_{DIV} at a time point t6, where the output logic 307 may set the calibration value N_{CAL} to one in response to D1=1 and D2=0. FIG. 5 is a diagram illustrating associated signals (e.g. the input signal RO_{DIV}, the clock signal CLK, the node signals N1 and N2, the delayed input signal ROD_{DIV} and the calibration signal VCAL) of the calibration circuit 103 under a second condition (e.g. ΔT_{S}<0.5×T_{CLK} and ΔT_{E}>0.5×T_{CLK}) according to an embodiment of the present invention. In this embodiment, the flip-flop 301 may pull the node signal N1 to the logic value “1” in response to a rising edge of the clock signal CLK at a time point t1, and pull the node signal N1 to the logic value “0” in response to a rising edge of the clock signal CLK at a time point t2. As the time difference ΔT_{S} is less than the half cycle of the clock signal CLK, the node signal N2 has the logic value “0” at a time point t3, such that the flip-flop 303 may maintain the calibration signal VCAL at the logic value “0” at the time point t3 instead of pulling the calibration signal VCAL to the logic value “1” in response to a falling edge of the clock signal CLK at the time point t3. In addition, as the time difference ΔT_{E} is greater than the half cycle of the clock signal CLK, the node signal N2 has the logic value “1” at a time point t4, such that the flip-flop 303 can pull the calibration signal VCAL to the logic value “1” in response to a falling edge of the clock signal CLK at the time point t4. Thus, the flip-flop 305 may output the determination bit D1 having the logic value “0” in response to a rising edge of the delayed input signal ROD_{DIV} at a time point t5, and the flip-flop 306 may output the determination bit D2 having the logic value “1” in response to a falling edge of the delayed input signal ROD_{DIV} at a time point t6, where the output logic 307 may set the calibration value N_{CAL} to zero in response to D1=0 and D2=1.

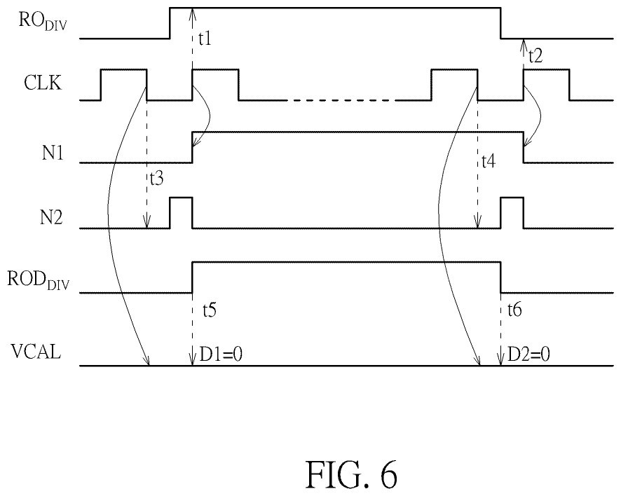

FIG. 6 is a diagram illustrating associated signals (e.g. the input signal RO_{DIV}, the clock signal CLK, the node signals N1 and N2, the delayed input signal ROD_{DIV}, and the calibration signal VCAL) of the calibration circuit 103 under a third condition (e.g. ΔT_{S}<0.5×T_{CLK} and ΔT_{E}<0.5×T_{CLK}) according to an embodiment of the present invention. In this embodiment, the flip-flop 301 may pull the node signal N1 to the logic value “1” in response to a rising edge of the clock signal CLK at a time point t1, and pull the node signal N1 to the logic value “0” in response to a rising edge of the clock signal CLK at a time point t2. As the time difference ΔT_{S} is less than the half cycle of the clock signal CLK, the node signal N2 has the logic value “0” at a time point t3, such that the flip-flop 303 may maintain the calibration signal VCAL at the logic value “0” at the time point t3 instead of pulling the calibration signal VCAL to the logic value “1” in response to a falling edge of the clock signal CLK at the time point t3. In addition, as the time difference ΔT_{E} is less than the half cycle of the clock signal CLK, the node signal N2 has the logic value “0” at a time point t4, such that the flip-flop 303 may maintain the calibration signal VCAL at the logic value “0” at the time point t4 instead of pulling the calibration signal VCAL to the logic value “1” in response to a falling edge of the clock signal CLK at the time point t4. Thus, the flip-flop 305 may output the determination bit D1 having the logic value “0” in response to a rising edge of the delayed input signal ROD_{DIV} at a time point t5, and the flip-flop 306 may output the determination bit D2 having the logic value “0” in response to a falling edge of the delayed input signal ROD_{DIV} at a time point t6, where the output logic 307 can set the calibration value N_{CAL} to zero in response to D1=0 and D2=0.

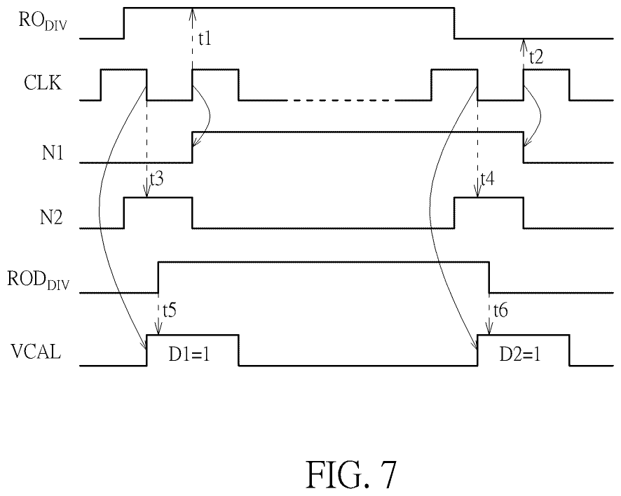

FIG. 7 is a diagram illustrating associated signals (e.g. the input signal RO_{DIV}, the clock signal CLK, the node signals N1 and N2, the delayed input signal ROD_{DIV}, and the calibration signal VCAL) of the calibration circuit 103 under a fourth condition (e.g. ΔT_{S}>0.5×T_{CLK} and ΔT_{E}>0.5×T_{CLK}) according to an embodiment of the present invention. In this embodiment, the flip-flop 301 may pull the node signal N1 to the logic value “1” in response to a rising edge of the clock signal CLK at a time point t1, and pull the node signal N1 to the logic value “0” in response to a rising edge of the clock signal CLK at a time point t2. As the time difference ΔT_{S} is greater than the half cycle of the clock signal CLK, the node signal N2 has the logic value “1” at a time point t3, such that the flip-flop 303 may pull the calibration signal VCAL to the logic value “1” in response to a falling edge of the clock signal CLK at the time point t3. In addition, as the time difference ΔT_{E} is greater than the half cycle of the clock signal CLK, the node signal N2 has the logic value “1” at a time point t4, such that the flip-flop 303 may pull the calibration signal VCAL to the logic value “1” in response to a falling edge of the clock signal CLK at the time point t4. Thus, the flip-flop 305 may output the determination bit D1 having the logic value “1” in response to a rising edge of the delayed input signal ROD_{DIV} at a time point t5, and the flip-flop 306 may output the determination bit D2 having the logic value “1” in response to a falling edge of the delayed input signal ROD_{DIV} at a time point t6, where the output logic 307 may set the calibration value N_{CAL} to zero in response to D1=1 and D2=1.

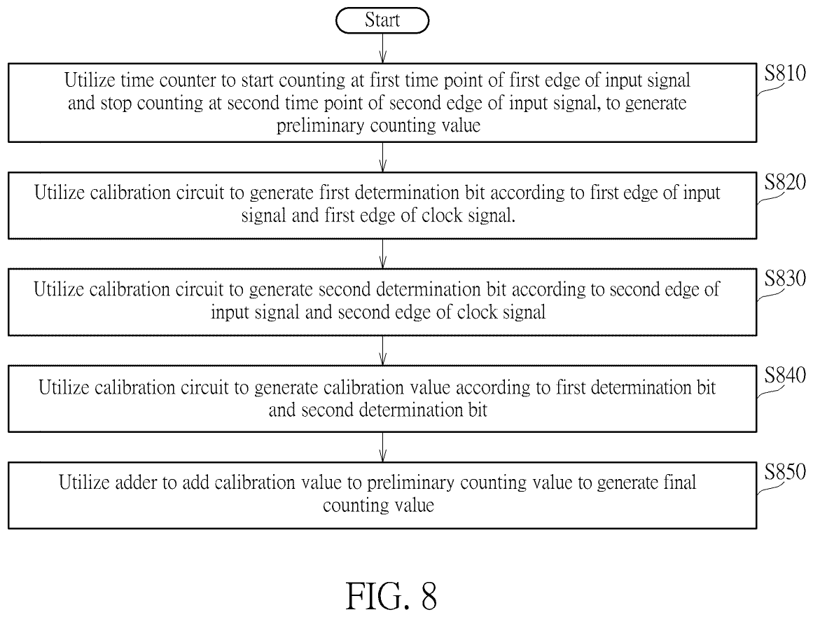

FIG. 8 is a diagram illustrating a working flow of a calibration method for performing time-to-digital conversion on an input signal (e.g. the time length of the high logic level duty cycle or the low logic level duty cycle of the input signal RO_{DIV} shown in FIG. 1) according to an embodiment of the present invention, where the calibration method may be executed by a TDC (e.g. the TDC 100 shown in FIG. 1). It should be noted that the working flow shown in FIG. 8 is for illustrative purposes only, and is not meant to be a limitation of the present invention. For example, one or more steps may be added, deleted, or modified in the working flow shown in FIG. 8. In addition, if a same result can be obtained, these steps do not have to be executed in the exact order shown in FIG. 8.

In Step S810, the TDC may utilize a time counter therein to start counting at a first time point of a first edge of an input signal and stop counting at a second time point of a second edge of the input signal, to generate a preliminary counting value.

In Step S820, the TDC may utilize a calibration circuit therein to generate a first determination bit according to the first edge of the input signal and a first edge of a clock signal.

In Step S830, the TDC may utilize the calibration circuit to generate a second determination bit according to the second edge of the input signal and a second edge of the clock signal.

In Step S840, the TDC may utilize the calibration circuit to generate a calibration value according to the first determination bit and the second determination bit.

In Step S850, the TDC may utilize an adder therein to add the calibration value to the preliminary counting value to generate a final counting value.

In summary, the TDC of the present invention can determine whether the preliminary counting value N_{CNT} outputted by the time counter needs to be calibrated (e.g. incremented by one) according to the time difference between the starting time point of the time length to be measured and the rising edge of the clock signal as well as the time difference between the ending time point of the time length to be measured and the rising edge of the clock signal, so as to reduce the error of the TDC within 0.5×T_{CLK}. In addition, the embodiments of the present invention will not significantly increase additional costs (e.g. circuit area and/or power consumption). Thus, the present invention can improve the overall performance of the TDC without introducing any side effect or in a way that is less likely to introduce side effects.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A time-to-digital converter (TDC), comprising:
a time counter, configured to start counting at a first time point of a first edge of an input signal and stop counting at a second time point of a second edge of the input signal, to generate a preliminary counting value;
a calibration circuit, configured to generate a first determination bit according to the first edge of the input signal and a first edge of a clock signal, generate a second determination bit according to the second edge of the input signal and a second edge of the clock signal, and generate a calibration value according to the first determination bit and the second determination bit; and
an adder, coupled to the time counter and the calibration circuit, configured to add the calibration value to the preliminary counting value to generate a final counting value.

2. The TDC of claim 1, wherein the first determination bit indicates whether a first time difference between the first edge of the input signal and the first edge of the clock signal is greater than a half cycle of the clock signal, and the second determination bit indicates whether a second time difference between the second edge of the input signal and the second edge of the clock signal is greater than the half cycle of the clock signal.

3. The TDC of claim 2, wherein when the first determination bit indicates that the first time difference is greater than the half cycle of the clock signal and the second determination bit indicates that the second time difference is less than the half cycle of the clock signal, the calibration value generated by the calibration circuit is one.

4. The TDC of claim 2, wherein when the first determination bit indicates that the first time difference is less than the half cycle of the clock signal or the second determination bit indicates that the second time difference is greater than the half cycle of the clock signal, the calibration value generated by the calibration circuit is zero.

5. The TDC of claim 1, wherein the preliminary counting value represents a number of rising edges of the clock signal during a counting period between the first time point and the second time point, the first edge of the clock signal represents a first rising edge of the clock signal after the first edge of the input signal, and the second edge of the clock signal represents a first rising edge of the clock signal after the second edge of the input signal.

6. The TDC of claim 1, wherein the preliminary counting value represents a number of falling edges of the clock signal during a counting period between the first time point and the second time point, the first edge of the clock signal represents a first falling edge of the clock signal after the first edge of the input signal, and the second edge of the clock signal represents a first falling edge of the clock signal after the second edge of the input signal.

7. The TDC of claim 1, wherein the calibration circuit comprises:
a first flip-flop, configured to sample the input signal according to rising edges of the clock signal to generate a first node signal;
an exclusive-OR gate, coupled to the first flip-flop, configured to perform an exclusive-OR operation on the input signal and the first node signal to generate a second node signal; and
a second flip-flop, coupled to the exclusive-OR gate, configured to sample the second node signal according to falling edges of the clock signal to generate a calibration signal, wherein a value of the calibration signal at a first delayed time point corresponding to the first time point represents the first determination bit, and a value of the calibration signal at a second delayed time point corresponding to the second time point represents the second determination bit.

8. The TDC of claim 7, wherein the calibration circuit further comprises:
a delay circuit, configured to delay the input signal to generate a delayed input signal, wherein the delay circuit delays the first edge and the second edge of the input signal to generate a first delayed edge and a second delayed edge of the delayed input signal, respectively;
a third flip-flop, coupled to the second flip-flop and the delay circuit, configured to sample the calibration signal at the first delayed time point according to the first delayed edge of the delayed input signal, in order to generate the first determination bit; and
a fourth flip-flop, coupled to the second flip-flop and the delay circuit, configured to sample the calibration signal at the second delayed time point according to the second delayed edge of the delayed input signal, in order to generate the second determination bit.

9. A calibration method for performing time-to-digital conversion on an input signal, comprising:
starting counting at a first time point of a first edge of an input signal and stopping counting at a second time point of a second edge of the input signal, to generate a preliminary counting value;
generating a first determination bit according to the first edge of the input signal and a first edge of a clock signal;
generating a second determination bit according to the second edge of the input signal and a second edge of the clock signal;
generating a calibration value according to the first determination bit and the second determination bit; and
adding the calibration value to the preliminary counting value to generate a final counting value.

10. The calibration method of claim 9, wherein the first determination bit indicates whether a first time difference between the first edge of the input signal and the first edge of the clock signal is greater than a half cycle of the clock signal, and the second determination bit indicates whether a second time difference between the second edge of the input signal and the second edge of the clock signal is greater than the half cycle of the clock signal.

11. The calibration method of claim 10, wherein generating the calibration value according to the first determination bit and the second determination bit comprises:
in response to the first determination bit indicating that the first time difference is greater than the half cycle of the clock signal and the second determination bit indicating that the second time difference is less than the half cycle of the clock signal, setting the calibration value to one.

12. The calibration method of claim 10, wherein generating the calibration value according to the first determination bit and the second determination bit comprises:
in response to the first determination bit indicating that the first time difference is less than the half cycle of the clock signal or the second determination bit indicating that the second time difference is greater than the half cycle of the clock signal, setting the calibration value to zero.

13. The calibration method of claim 9, wherein the preliminary counting value represents a number of rising edges of the clock signal during a counting period between the first time point and the second time point, the first edge of the clock signal represents a first rising edge of the clock signal after the first edge of the input signal, and the second edge of the clock signal represents a first rising edge of the clock signal after the second edge of the input signal.

14. The calibration method of claim 9, wherein the preliminary counting value represents a number of falling edges of the clock signal during a counting period between the first time point and the second time point, the first edge of the clock signal represents a first falling edge of the clock signal after the first edge of the input signal, and the second edge of the clock signal represents a first falling edge of the clock signal after the second edge of the input signal.

15. The calibration method of claim 9, wherein generating the calibration value according to the first determination bit and the second determination bit comprises:
sampling the input signal according to rising edges of the clock signal to generate a first node signal;
performing an exclusive-OR operation on the input signal and the first node signal to generate a second node signal; and
sampling the second node signal according to falling edges of the clock signal to generate a calibration signal;
wherein a value of the calibration signal at a first delayed time point corresponding to the first time point represents the first determination bit, and a value of the calibration signal at a second delayed time point corresponding to the second time point represents the second determination bit.

16. The calibration method of claim 15, wherein generating the calibration value according to the first determination bit and the second determination bit further comprises:
delaying the first edge and the second edge of the input signal to generate a first delayed edge and a second delayed edge of a delayed input signal, respectively;
sampling the calibration signal at the first delayed time point according to the first delayed edge of the delayed input signal, in order to generate the first determination bit; and
sampling the calibration signal at the second delayed time point according to the second delayed edge of the delayed input signal, in order to generate the second determination bit.
